(19) United States
(12) Patent Application Publication
(10) Pub. No.: US 2009/0057644 A1
(43) Pub. Date: Mar. 5, 2009

(54) Phase-change memory units, methods of forming the phase-change memory units, phase-change memory devices having the phase-change memory units and methods of manufacturung the phase-change memory devices

(75) Inventors: Hee-Ju Shin, Yongin-si (KR); Yong-Ho Ha, Hwaseong-si (KR); Jeong-Hee Park, Hwaseong-si (KR); Myung-Jin Kang, Suwon-si (KR); Doo-Hwan Park, Seoul (KR)

Correspondence Address: MILLS & ONELLO LLP, ELEVEN BEACON STREET, SUITE 605, BOSTON, MA, 02108, US

(73) Assignee: Samsung Electronics Co., LTD, Suwon-si (KR)

(21) Appl. No.: 12/229,500

(22) Filed: Aug. 22, 2008

(30) Foreign Application Priority Data
Aug. 24, 2007 (KR) 10-2007-0085582

(51) Int. Cl. H01L 45/00

(52) U.S. Cl. 257/4; 438/102; 257/E45.002

(57) ABSTRACT

A phase-change memory unit includes a lower electrode on a substrate, a phase-change material layer pattern including germanium-antimony-tellurium (GST) and carbon on the lower electrode, a transition metal layer pattern on the phase-change material layer pattern, and an upper electrode on the first transition metal layer pattern. The phase-change memory unit may have good electrical characteristics.

### CROSS REFERENCE TO RELATED APPLICATION

This application claims priority under 35 USC § 119 to Korean Patent Application No. 2007-85582, filed on Aug. 24, 2007, in the Korean Intellectual Property Office (KIPO), the contents of which are herein incorporated by reference in their entirety.

### BACKGROUND

1. Field

Exemplary embodiments relate to phase-change memory units, methods of forming the phase-change memory units, phase-change memory devices having the phase-change memory units and methods of manufacturing the phase-change memory devices. More particularly, exemplary embodiments relate to phase-change memory units having improved structures, methods of forming the phase-change memory units, phase-change memory devices having the phase-change memory units and methods of manufacturing the phase-change memory devices.

2. Description of the Related Art

Data can be stored in a cell of a phase-change memory (PRAM) device using a resistance difference between an amorphous state and a crystalline state of a phase-change material layer including a chalcogenide material. For example, data “0” and “1” can be stored in a cell of the PRAM device using a reversible phase-change of the phase-change material layer including the chalcogenide material that may occur according to the amplitude and wavelength of a pulse applied to the phase-change material layer. A reset current used to change the phase-change material layer from a crystalline state into an amorphous state and a set current used to change the phase-change material layer from the amorphous state into the crystalline state may flow by a transistor or a diode and through a lower electrode to the phase-change material layer, thereby generating the phase-change of the phase-change material layer.

Recently, research has been conducted to improve the electrical characteristics and reliability of a PRAM device by adding carbon, or carbon and nitrogen into the chalcogenide material of the phase-change material layer. However, in a PRAM device having a chalcogenide material including carbon, when the carbon concentration is relatively low, the PRAM device may not have sufficiently improved reliability. On the other hand, when the carbon concentration is relatively high, the PRAM device may have increased set resistance.

### SUMMARY

Exemplary embodiments provide a phase-change memory unit having good electrical characteristics and an improved reliability, and a method of forming the same. Exemplary embodiments provide a phase-change memory device having good electrical characteristics and an improved reliability, and a method of manufacturing the same.

According to some exemplary embodiments, there is provided a phase-change memory unit. The phase-change memory unit includes a lower electrode on a substrate, a phase-change material layer pattern including germanium-antimony-tellurium (GST) and carbon on the lower electrode, a first transition metal layer pattern on the phase-change material layer pattern, and an upper electrode on the first transition metal layer pattern.

In exemplary embodiments, the first transition metal layer pattern may include titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof.

In exemplary embodiments, the first transition metal layer pattern may have a thickness of about 20 to about 100 Å.

In exemplary embodiment, the upper electrode may include a metal nitride.

In exemplary embodiment, the upper electrode may include titanium nitride, titanium aluminum nitride, tantalum nitride, tungsten nitride, or molybdenum nitride. These materials may be used alone or in a combination thereof.

In exemplary embodiments, the phase-change material layer pattern may have formula (1).

C_{A}M_{B}[Ge_{X}Sb_{Y}Te_{(100-X-Y)}]_{(100-A-B)} (1),

wherein C represents carbon, and M represents metal. A, B, X and Y may satisfy inequalities 0.2≦A≦25.0, 0.0≦B≦10.0, 0.1≦X≦30.0, and 0.1≦Y≦90.0.

In exemplary embodiments, the metal represented by M may include aluminum (Al), gallium (Ga), indium (In), titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof.

In exemplary embodiments, the phase-change material layer pattern may have formula (2).

C_{A}M_{B}[Ge_{X}Z_{(100-X)}Sb_{Y}Te_{(100-X-Y)}]_{(100-A-B)} (2),

wherein Z represents silicon or tin. A, B, X and Y may satisfy inequalities 0.2≦A≦25.0, 0.0≦B≦10.0, 0.1≦X≦80.0, and 0.1≦y≦90.0.

In exemplary embodiments, the phase-change material layer pattern may have formula (3).

C_{A}M_{B}[Ge_{X}Sb_{Y}T_{(100-y)}Te_{(100-X-Y)}]_{(100-A-B)} (3),

wherein T represents arsenic or bismuth. A, B, X and Y may satisfy inequalities 0.2≦A≦25.0, 0.0≦B≦10.0, 0.1≦X≦90.0, and 0.1≦Y≦80.0.

In exemplary embodiments, the phase-change material layer pattern may have formula (4).

C_{A}M_{B}[Ge_{X}Sb_{Y}Q_{(100-X-Y)}]_{(100-A-B)} (4),

wherein Q represents antimony and selenium. A, B, X and Y may satisfy inequalities 0.2≦A≦25.0, 0.0≦B≦10.0, 0.1≦X≦90.0, and 0.1≦Y≦90.0.

In exemplary embodiments, the phase-change memory material layer pattern may further include nitrogen.

In exemplary embodiments, the lower electrode may include a metal or a metal nitride.

In exemplary embodiments, the lower electrode may include a metal nitride, and the phase-change memory unit may further include a second transition metal layer pattern between the lower electrode and the phase-change material layer pattern.

In exemplary embodiments, the second transition metal layer pattern may include titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof.

In exemplary embodiments, the second transition metal layer pattern may have a thickness of no more than about 15 Å.

According to some exemplary embodiments, there is provided a method of forming a phase-change memory unit. In the method, a lower electrode is formed on a substrate. A phase-change material layer pattern including GST and carbon is formed on the lower electrode. A first transition metal layer pattern is formed on the phase-change material layer pattern. An upper electrode is formed on the first transition metal layer pattern. In exemplary embodiments, the first transition metal layer pattern may be formed using titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof. In exemplary embodiments, the first transition metal layer pattern may be formed to have a thickness of about 20 to about 100 Å.

In exemplary embodiments, the upper electrode may be formed using a metal nitride.

In exemplary embodiments, the phase-change material layer pattern may have a formula of C_{A}M_{B}[Ge_{X}Sb_{Y}Te_{(100-X-Y)}]_{(100-A-B)}, wherein C represents carbon, and M represents metal. A, B, X and Y may satisfy inequalities 0.2≦A≦25.0, 0.0≦B≦10.0, 0.1≦X≦30.0, and 0.1≦Y≦90.0.

In exemplary embodiments, the lower electrode may be formed using a metal nitride, and a second transition metal layer pattern may be further formed on the lower electrode.

According to some exemplary embodiments, there is provided a phase-change memory device. The phase-change memory device includes a switching element on a substrate, a lower electrode electrically connected to the switching element, a phase-change material layer pattern including GST and carbon on the lower electrode, a first transition metal layer pattern on the phase-change material layer pattern, and an upper electrode on the first transition metal layer pattern.

In exemplary embodiments, the first transition metal layer pattern may include titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof. In exemplary embodiments, the upper electrode may include a metal nitride. In exemplary embodiments, the phase-change material layer pattern may have a formula of C_{A}M_{B}[Ge_{X}Sb_{Y}Te_{(100-X-Y)}]_{(100-A-B)}, wherein C represents carbon, and M represents metal. A, B, X and Y satisfy inequalities 0.2≦A≦25.0, 0.0≦B≦10.0, 0.1≦X≦30.0, and 0.1≦Y≦90.0.

In exemplary embodiments, the lower electrode may include a metal nitride, and the phase-change memory device may further include a second transition metal layer pattern between the lower electrode and the phase-change material layer pattern.

In exemplary embodiments, the switching element may include a diode on the substrate, and the lower electrode may be electrically connected to the diode. In exemplary embodiments, the switching element may include a transistor having a gate structure on the substrate, and an impurity region at an upper portion of the substrate adjacent to the gate structure. The lower electrode may be electrically connected to the impurity region.

According to some exemplary embodiments, there is provided a method of manufacturing a phase-change memory device. In the method, a switching element is formed on a substrate. A lower electrode electrically connected to the switching element is formed. A phase-change material layer pattern including GST and carbon is formed on the lower electrode. A first transition metal layer pattern is formed on the phase-change material layer pattern. An upper electrode is formed on the first transition metal layer pattern.

In exemplary, the first transition metal layer pattern may be formed using titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), or platinum (Pt). These metals may be used alone or in a combination thereof.

In exemplary embodiments, the upper electrode may be formed using a metal nitride.

In exemplary embodiments, the phase-change material layer pattern may have a formula of C_{A}M_{B}[Ge_{X}Sb_{Y}Te_{(100-X-Y)}]_{(100-A-B)}, wherein C represents carbon, and M represents metal. A, B, X and Y satisfy inequalities 0.2≦A≦25.0, 0.0≦B≦10.0, 0.1≦X≦30.0, and 0.1≦Y≦90.0.

In exemplary embodiments, the lower electrode may be formed using a metal nitride, and a second transition metal layer pattern may be further formed between the lower electrode and the phase-change material layer pattern.

In exemplary embodiments, when the switching element is formed, a diode may be formed on the substrate, and the lower electrode may be formed to be electrically connected to the diode.

In exemplary embodiments, when the switching element is formed, a gate structure may be formed on the substrate. An impurity region may be formed at an upper portion of the substrate adjacent to the gate structure. The lower electrode may be formed to be electrically connected to the impurity region.

According to some exemplary embodiments, the phase-change memory device has a transition metal layer pattern between a phase-change material layer pattern including GST and carbon, and an upper electrode including a metal nitride. The amount of metal included in the upper electrode diffusing into the phase-change material layer pattern may decrease, so that power consumption may decrease because of a decrease in a reset current, and a sensing margin may not decrease because reset resistance does not decrease. Additionally, even though the phase-change material layer pattern has a relatively low concentration of carbon, the phase-change memory device may have good data retention and good endurance due to the transition metal layer pattern.

### BRIEF DESCRIPTION OF THE DRAWINGS

Exemplary embodiments will be more clearly understood from the following detailed description taken in conjunction with the accompanying drawings. FIGS. 1 to 10 represent non-limiting, exemplary embodiments as described herein.

FIG. 1 is a cross-sectional view illustrating a phase-change memory unit in accordance with some exemplary embodiments;

FIG. 2 is a cross-sectional view illustrating a phase-change memory unit in accordance with other exemplary embodiments;

FIGS. 3A to 3I are graphs illustrating changes of electrical resistances of the phase-change memory unit in accordance with some exemplary embodiments when the thickness of the first transition metal layer pattern and the concentration of carbon in the phase-change material layer pattern had various values;

FIG. 4 is a graph illustrating endurance characteristics of the phase-change memory unit in accordance with some exemplary embodiments with respect to a thickness of the first transition metal layer pattern;

FIGS. 5A to 5D are cross-sectional views illustrating a method of forming a phase-change memory unit in accordance with some exemplary embodiments;

FIGS. 6A and 6B are cross-sectional views illustrating a method of forming a phase-change memory unit in accordance with other exemplary embodiments;

FIG. 7 is a cross-sectional view illustrating a phase-change memory device in accordance with some exemplary embodiments;

FIG. 8 is a cross-sectional view illustrating a phase-change memory device in accordance with other exemplary embodiments;

FIG. 9 is a cross-sectional view illustrating a phase-change memory device in accordance with still other exemplary embodiments;

FIG. 10 is a cross-sectional view illustrating a phase-change memory device in accordance with other exemplary embodiments;

FIGS. 11A to 11D are cross-sectional views illustrating a method of manufacturing a phase-change memory device in accordance with some exemplary embodiments;

FIGS. 12A to 12B are cross-sectional views illustrating a method of manufacturing a phase-change memory device in accordance with other exemplary embodiments;

FIGS. 13A to 13D are cross-sectional views illustrating a method of manufacturing a phase-change memory device in accordance with still other exemplary embodiments; and

FIGS. 14A to 14B are cross-sectional views illustrating a method of manufacturing a phase-change memory device in accordance with other exemplary embodiments.

### DETAILED DESCRIPTION OF THE EMBODIMENTS

Various exemplary embodiments will be described more fully hereinafter with reference to the accompanying drawings, in which some exemplary embodiments are shown. The present invention may, however, be embodied in many different forms and should not be construed as limited to the exemplary embodiments set forth herein. Rather, these exemplary embodiments are provided so that this disclosure will be thorough and complete. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section without departing from the teachings of this disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative terms used herein interpreted accordingly.

The terminology used herein is for the purpose of describing particular exemplary embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances are to be expected. Thus, exemplary embodiments should not be construed as limited to the particular shapes of regions illustrated herein but are to include deviations in shapes that result, for example, from manufacturing. For example, an implanted region illustrated as a rectangle can have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

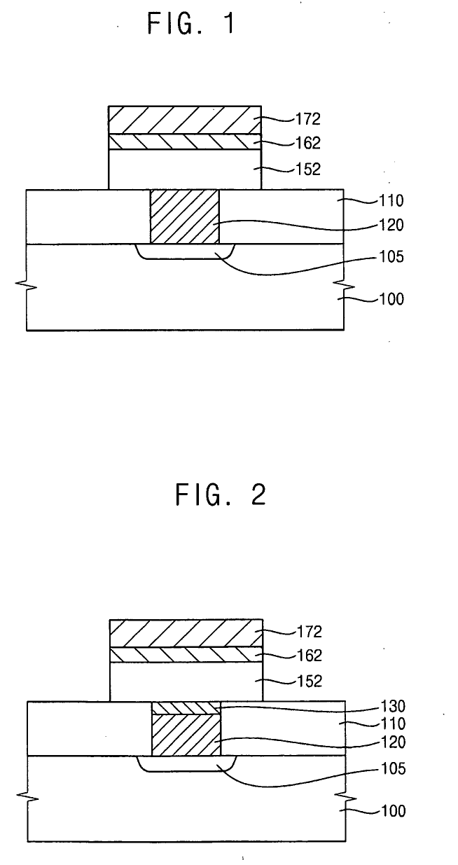

FIG. 1 is a cross-sectional view illustrating a phase-change memory unit in accordance with some exemplary embodiments.

Referring to FIG. 1, the phase-change memory unit includes a substrate 100 having a lower structure therein, an insulating structure 110, a lower electrode 120, a phase-change material layer pattern 152, a first transition metal layer pattern 162 and an upper electrode 172.

The substrate 100 may include a semiconductor substrate. For example, the substrate 100 may include a silicon substrate, a germanium substrate, a silicon-germanium substrate, a silicon-on-insulator (SOI) substrate, a germanium-on-insulator (GOI) substrate, etc. The lower structure may be formed in or on the substrate 100, and include an impurity region 105, a pad, a plug, a contact, a conductive pattern, an insulation layer pattern, a gate structure and/or a transistor. As shown, the lower structure includes the impurity region 105 at an upper portion of the substrate 100.

The insulating structure 110 is formed on the substrate 100 to partially cover the lower structure. The insulating structure 110 may electrically insulate the phase-change material layer pattern 152 from the lower structure. Additionally, when a plurality of phase-change memory units is formed on the substrate 100, the insulating structure 110 may electrically insulate the phase-change memory units from each other. In exemplary embodiments, the insulating structure 110 has a single-layered structure including an oxide, a nitride or an oxynitride. Alternatively, the insulating structure 110 may have a multi-layered structure in which at least one oxide layer, at least one nitride layer and/or at least one oxynitride layer are sequentially or alternately stacked. The oxide layer may include silicon oxide. The nitride layer may include silicon nitride. The oxynitride layer may include silicon oxynitride. For example, the oxide layer may include boro-phosphor silicate glass (BPSG), phosphor silicate glass (PSG), undoped silicate glass (USG), spin on glass (SOG), tetraethylorthosilicate (TEOS), plasma enhanced tetraethylorthosilicate (PE-TEOS), high density plasma chemical vapor deposition (HDP-CVD) oxide, etc.

The insulating structure 110 includes an opening (not shown) that exposes the impurity region 105. The impurity region 105 may be formed by implanting impurities into a portion of the substrate 100.

The lower electrode 120 is formed on the impurity region 105 to fill the opening. The lower electrode 120 may include a metal or a metal compound. For example, the lower electrode 120 may include tungsten, aluminum, copper, tantalum, titanium, molybdenum, niobium, zirconium, aluminum nitride, titanium aluminum nitride, titanium nitride, tungsten nitride, tantalum nitride, molybdenum nitride, molybdenum titanium nitride, molybdenum aluminum nitride, niobium nitride, titanium boron nitride, tungsten boron nitride, zirconium aluminum nitride, tantalum aluminum nitride, zirconium silicon nitride, tantalum silicon nitride, molybdenum silicon nitride, tungsten silicon nitride, titanium silicon nitride, etc. These materials may be used alone or in a combination thereof. In an exemplary embodiment, the lower electrode 120 has a three-dimensional shape such as a cylinder, a polygonal pillar having an empty central portion, a cup, etc. In some embodiments, the lower electrode 120 does not completely fill the opening, and a filling structure (not shown) may be formed in the empty central portion of the lower electrode 120. The filling structure may include a nitride, such as silicon nitride, or an oxide, such as silicon oxide. The phase-change material layer pattern 152 is formed on the lower electrode 120 and the insulating structure 110. The phase-change material layer pattern 152 may have a width substantially larger than that of the lower electrode 120, and thus the phase-change material layer pattern 152 may be formed on both of the lower electrode 120 and the insulating structure 110. Alternatively, the phase-change material layer pattern 152 may have a width substantially the same as that of the lower electrode 120.

The phase-change material layer pattern 152 includes carbon and germanium-antimony-tellurium (GST). In exemplary embodiments, the phase-change material layer pattern 152 includes a material represented by formula (1).

C_{A}M_{B}[Ge_{X}Sb_{Y}Te_{(100-X-Y)}]_{(100-A-B)} (1)

C represents carbon, and M represents a metal. A, B, X and Y satisfy inequalities 0.2≦A≦25.0, 0.0≦B≦10, 0.1≦X≦30.0, and 0.1≦Y≦90.0.

In formula (1), the metal may include aluminum (Al), gallium (Ga), indium (In), titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), platinum (Pt), etc. These metals may be used alone or in a combination thereof.

In other exemplary embodiments, the phase-change material layer pattern 152 may include a material represented by formula (2), wherein germanium in formula (1) is substituted with germanium and silicon or germanium and tin.

C_{A}M_{B}[Ge_{X}Z_{(100-X)}Sb_{Y}Te_{(100-X-Y)}]_{(100-A-B)} (2)

Z represents silicon or tin. A, B, X and Y satisfy inequalities 0.2≦A≦25.0, 0.0≦B≦10.0, 0.1≦X≦80.0, and 0.1≦Y≦90.0.

In still other exemplary embodiments, the phase-change material layer pattern 152 includes a material represented by formula (3), wherein antimony in formula (1) is substituted with antimony and arsenic (As) or antimony and bismuth (Bi).

C_{A}M_{B}[Ge_{X}Sb_{Y}T_{(100-y)}Te_{(100-X-Y)}]_{(100-A-B)} (3)

T represents arsenic or bismuth. A, B, X and Y satisfy inequalities 0.2≦A≦25.0, 0.0≦B≦10.0, 0.1≦X≦90.0, and 0.1≦Y≦80.0.

In still other exemplary embodiments, the phase-change material layer pattern 152 includes a material represented by formula (4), wherein tellurium in formula (1) is substituted with antimony and selenium (Se).

C_{A}M_{B}[Ge_{X}Sb_{Y}Q_{(100-X-Y)}]_{(100-A-B)} (4)

Q represents antimony and selenium. A, B, X and Y satisfy inequalities 0.2≦A≦25.0, 0.0≦B≦10.0, 0.1≦X≦90.0, and 0.1≦Y≦90.0.

In still other exemplary embodiments, the phase-change material layer pattern 152 further includes nitrogen.

The first transition metal layer pattern 162 is formed on the phase-change material layer pattern 152. The first transition metal layer pattern 162 may have an area substantially the same as that of the phase-change material layer pattern 152.

The first transition metal layer pattern 162 includes a transition metal. For example, the first transition meta layer pattern 162 may include titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), platinum (Pt), etc. These metals may be used alone or in a combination thereof.

In exemplary embodiments, the first transition metal layer pattern 162 has a thickness of about 20 to about 100 Å.

The upper electrode 172 is formed on the first transition metal layer pattern 162. The upper electrode 172 may have an area substantially the same as that of the first transition metal layer pattern 162 and the phase-change material layer pattern 152. In some exemplary embodiments, the upper electrode 172 includes a metal nitride. For example, the upper electrode 172 may include titanium nitride, titanium aluminum nitride, tantalum nitride, tungsten nitride or molybdenum nitride, etc. These may be used alone or in a combination thereof. In exemplary embodiments, the upper electrode 172 has a thickness of about 200 to about 800 Å.

The phase-change memory unit illustrated with reference to FIG. 1 has the first transition metal layer pattern 162 between the phase-change material layer pattern 152 including GST and carbon, and the upper electrode 172 including a metal nitride. Thus, the phase-change memory unit is different from other phase-change memory units that have an upper electrode including a metal on a phase-change material layer pattern. In other phase-change memory units, as the metal of the upper electrode diffuses into the phase-change material layer pattern, power consumption can increase because of an increase in a reset current, and a sensing margin can decrease because of a decrease in a reset resistance. On the other hand, in the phase-change memory unit in accordance with some exemplary embodiments, the amount of metal of the upper electrode 162 diffusing into the phase-change material layer pattern 152 decreases, so power consumption may decrease because reset current does not increase, and a sensing margin may increase because reset resistance does not decrease. As a result, the phase-change memory unit in accordance with some exemplary embodiments has good electrical characteristics.

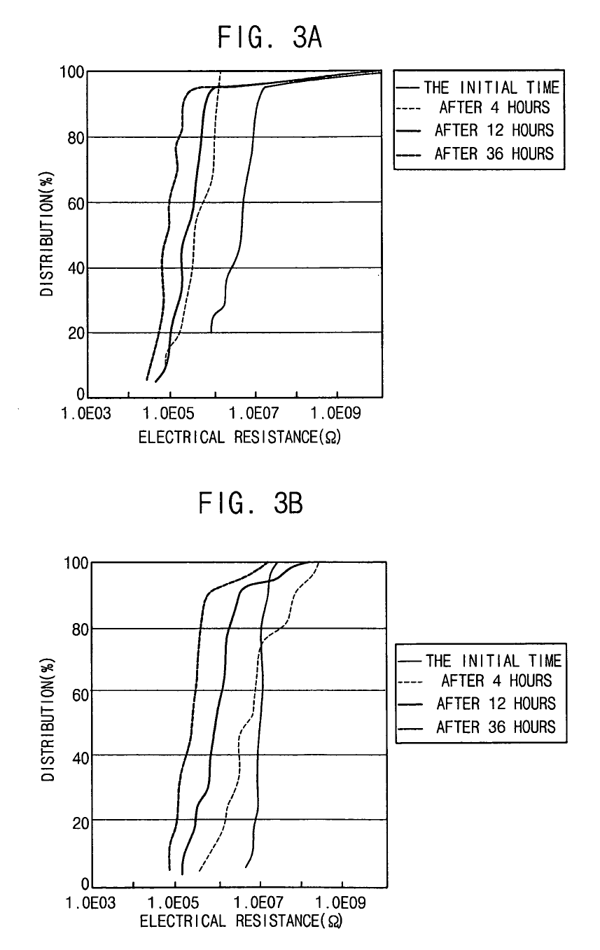

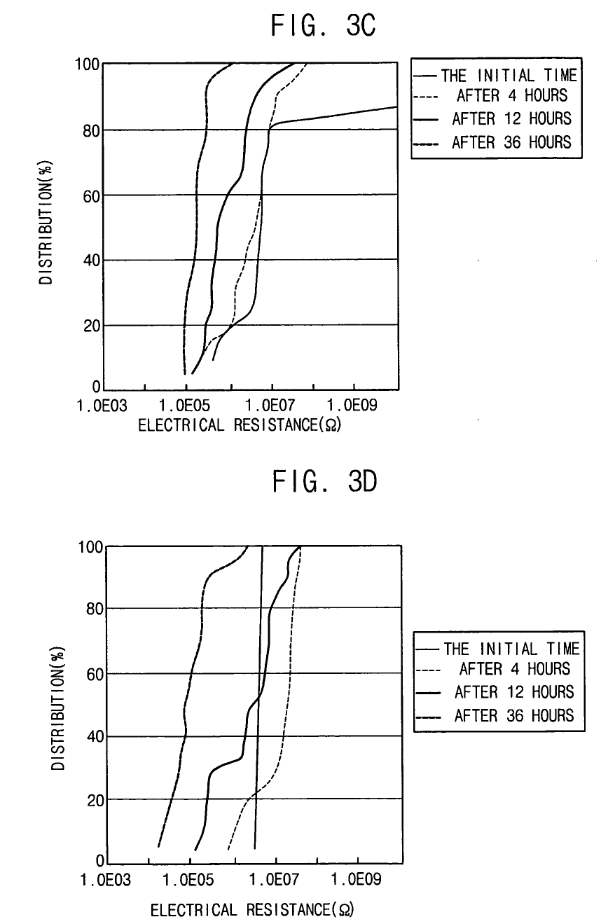

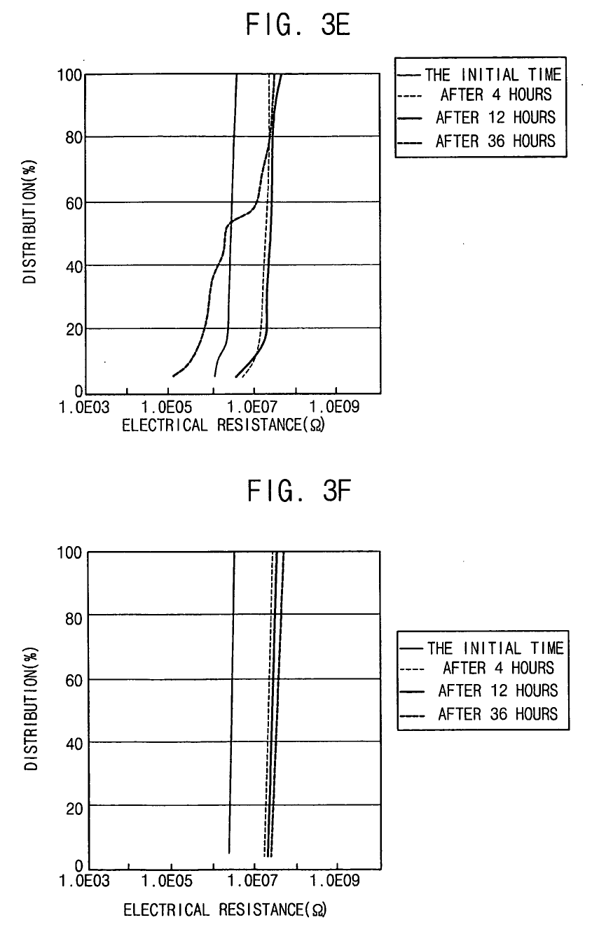

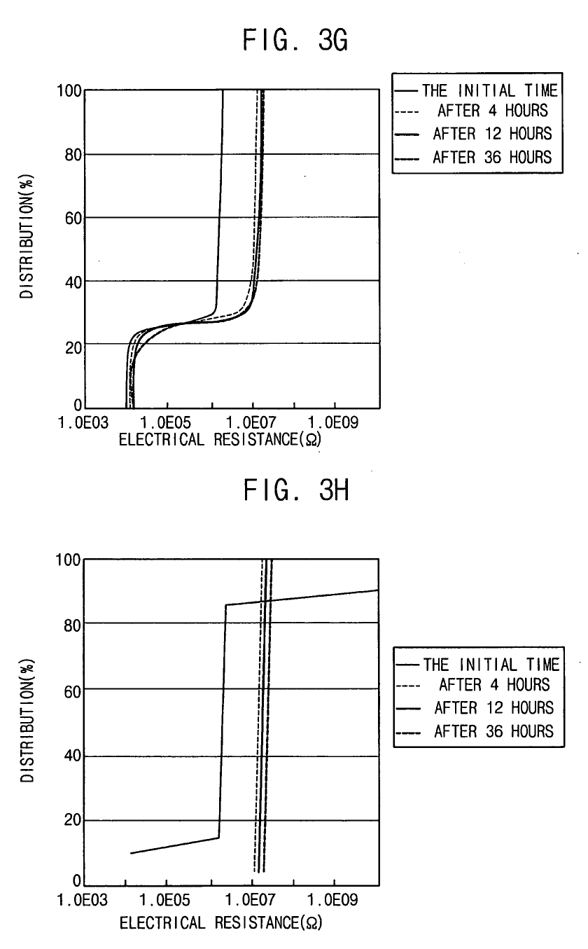

Additionally, the phase-change material layer pattern 152 may include carbon, however, the phase-change material layer pattern 152 need not include an amount of carbon (e.g., more than about 12% by weight of carbon based on the total weight thereof) such that the phase-change memory unit has a large set resistance. That is, even though a phase-change memory unit may have a higher reliability because a phase-change material layer pattern in the phase-change memory unit has a higher concentration of carbon, the phase-change memory unit may have an increased set resistance due to the high concentration of carbon. However, even though the phase-change material layer pattern 152 of the phase-change memory unit in accordance with some exemplary embodiments has a relatively low concentration of carbon, the phase-change memory unit may have enhanced data retention, which is illustrated with reference to FIGS. 3A to 3I.

FIGS. 3A to 3I are graphs illustrating changes in electrical resistance of the phase-change memory unit in accordance with some exemplary embodiments when the thickness of the first transition metal layer pattern and the concentration of carbon in the phase-change material layer pattern had various values. Particularly, FIGS. 3A to 3C are graphs illustrating the electrical resistance of the phase-change memory unit at several times when the first transition metal layer pattern was not formed and the phase-change material layer pattern had a concentration of about 6, 8.7 and 10%, respectively. FIGS. 3D to 3F are graphs illustrating the electrical resistance of the phase-change memory unit at several times when the first transition metal layer pattern had a thickness of about 40 Å and the phase-change material layer pattern had a concentration of about 6, 8.7 and 10%, respectively. FIGS. 3G to 3I are graphs illustrating the electrical resistance of the phase-change memory unit at several times when the first transition metal layer pattern had a thickness of about 60 Å and the phase-change material layer pattern had a concentration of about 6, 8.7 and 10%, respectively. The first transition metal layer pattern included titanium, and the electrical resistance was measured at the initial time, after 4 hours, after 12 hours and after 36 hours.

Referring to FIGS. 3A to 3I, when the first transition metal layer pattern had a thickness of about 60 Å, the electrical resistance after 4 hours, 12 hours and 36 hours was not reduced regardless of the carbon concentration when compared to that of the initial time, which means that the phase-change memory unit had good data retention. When the first transition metal layer pattern had a thickness of about 40 Å, the electrical resistance after 4 hours, 12 hours and 36 hours was not reduced at the carbon concentration of about 8.7% or about 10% when compared to that of the initial time, which means that the phase-change memory unit had good data retention. When the first transition metal layer pattern was not formed, the electrical resistance after 4 hours, 12 hours and 36 hours was reduced regardless of the carbon concentration when compared to that of the initial time, which means that the phase-change memory unit had poor data retention. As a result, the data retention characteristics may be better as the carbon concentration is increased and the first transition metal layer pattern has a larger thickness, and particularly, when the first transition metal layer pattern has a large thickness, the data retention characteristics may be good even though the carbon concentration is low.

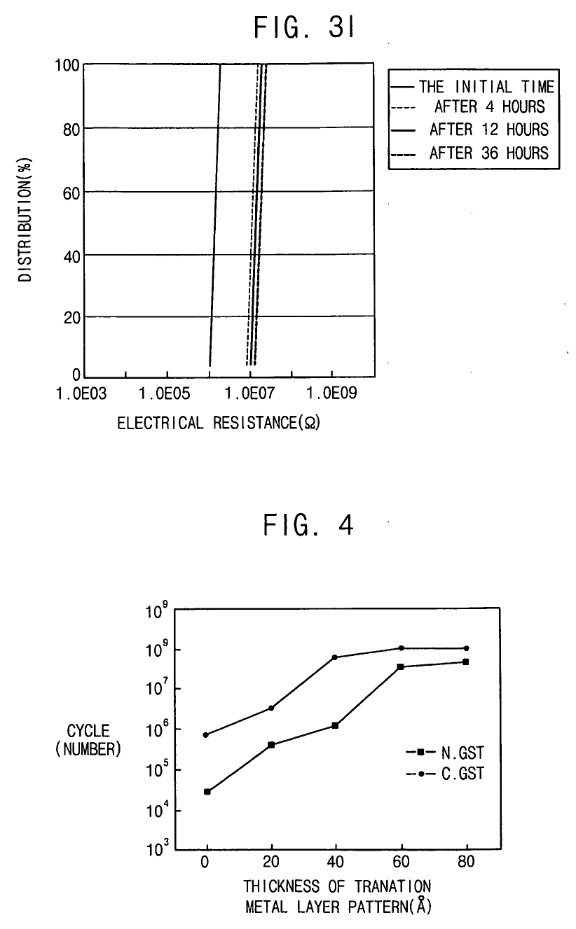

FIG. 4 is a graph illustrating endurance characteristics of the phase-change memory unit in accordance with some exemplary embodiments as a function of the thickness of the first transition metal layer pattern. In FIG. 4, “▪” indicates a cycle number at which data can be repeatedly input/output into/from the phase-change material layer pattern including GST doped with nitrogen as a function of the thickness of the first transition metal layer pattern including titanium, and “” indicates a cycle number at which data can be repeatedly input/output into/from the phase-change material layer pattern including GST doped with carbon as a function of the thickness of the first transition metal layer pattern including titanium.

Referring to FIG. 4, the phase-change memory unit having the phase-change material layer pattern including GST doped with carbon has better endurance than that of the phase-change memory unit having the phase-change material layer pattern including GST doped with nitrogen. Additionally, the phase-change memory unit may have better endurance because the first transition metal layer pattern has a larger thickness in both of the phase-change memory units.

FIG. 2 is a cross-sectional view illustrating a phase-change memory unit in accordance with other exemplary embodiments. The phase-change memory unit illustrated with reference to FIG. 2 is substantially the same as or similar to that of FIG. 1, except that a second transition metal layer pattern is formed between a lower electrode and a phase-change material layer pattern and the lower electrode may include other materials. Like numerals refer to like elements, and detailed explanations about the like elements are omitted here for the purpose of brevity.

Referring to FIG. 2, the phase-change memory unit includes a substrate 100 having a lower structure therein, an insulating structure 110, a lower electrode 120, a second transition metal layer pattern 130, a phase-change material layer pattern 152, a first transition metal layer pattern 162 and an upper electrode 172.

The lower electrode 120 may include a metal nitride. For example, the lower electrode 120 may include titanium nitride, titanium aluminum nitride, tantalum nitride, tungsten nitride, molybdenum nitride, etc. These may be used alone or in a combination thereof.

The second transition metal layer pattern 130 includes a transition metal. For example, the second transition metal layer pattern 130 may include titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), platinum (Pt), etc. These metals may be used alone or in a combination thereof.

In exemplary embodiments, the second transition metal layer pattern 130 has a thickness of no more than about 15 Å.

The phase-change memory unit illustrated with reference to FIG. 2 has not only the first transition metal layer pattern 162 between the phase-change material layer pattern 152 and the upper electrode 172, but also the second transition metal layer pattern 130 between the phase-change material layer pattern 152 and the lower electrode 120. The phase-change memory unit may have good data retention characteristics and set resistance distribution characteristics. The second transition metal layer pattern 130 has a thickness smaller than that of the first transition metal layer pattern 162, so the phase-change memory unit may not have an increased reset current.

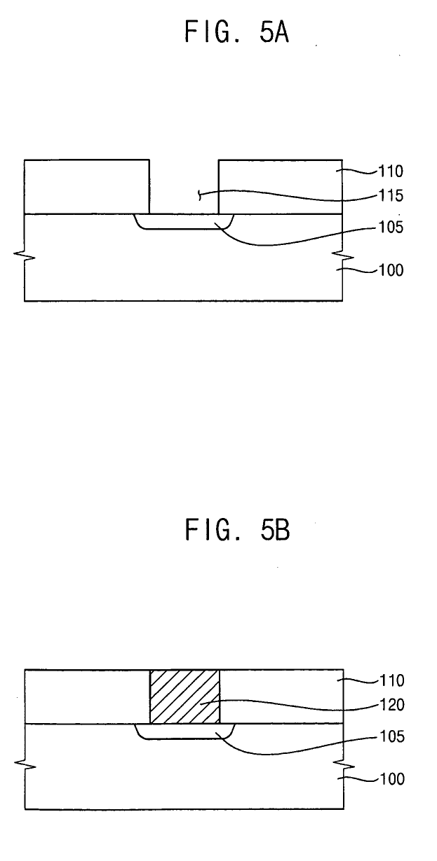

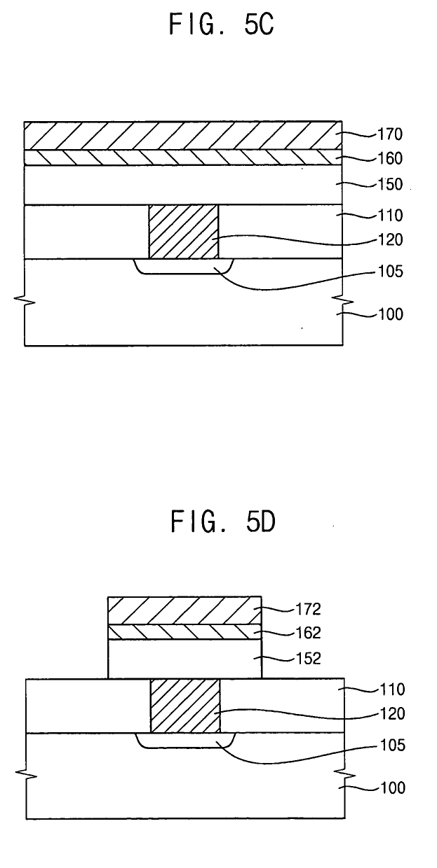

FIGS. 5A to 5D are cross-sectional views illustrating a method of forming a phase-change memory unit in accordance with some exemplary embodiments. Although a method of forming the phase-change memory unit in FIG. 1 is illustrated with reference to FIGS. 5A to 5D, exemplary embodiments illustrated with reference to FIGS. 5A to 5D are not restricted to forming the phase-change memory unit in FIG. 1.

Referring to FIG. 5A, a lower structure is formed on or in a substrate 100. The substrate 100 may include a semiconductor substrate. The lower structure may include an impurity region, a pad, a plug, a contact, a conductive pattern, an insulation layer pattern, a gate structure and/or a transistor.

In exemplary embodiments, impurities are implanted into a portion of the substrate 100 to form an impurity region 105. The impurity region 105 may be formed by an ion implantation process.

An insulating structure 110 is formed on the substrate 100 to cover the lower structure. The insulating structure 110 may be formed by a chemical vapor deposition (CVD) process, a low pressure chemical vapor deposition (LPCVD) process, a plasma enhanced chemical vapor deposition (PECVD) process, a high density plasma chemical vapor deposition (HDP-CVD) process, etc. In one exemplary embodiment, the insulating structure 110 has a single-layered structure including an oxide layer, a nitride layer or an oxynitride layer. The oxide layer, the nitride layer, and the oxynitride layer may include silicon oxide, silicon nitride, and silicon oxynitride, respectively. In other exemplary embodiments, the insulating structure 110 has a multi-layered structure in which at least one oxide layer, at least one nitride layer and/or at least one oxynitride layer are sequentially or alternately formed.

After forming a first photoresist pattern (not shown) on the insulating structure 110, the insulating structure 110 is partially removed using the first photoresist pattern as an etching mask, thereby forming an opening 115 exposing the impurity region 105. The first photoresist pattern may be removed by an ashing process and/or a stripping process.

Referring to FIG. 5B, a lower electrode 120 is formed on the impurity region 105 to fill the opening 115. More particularly, a lower electrode layer is formed on the insulating structure 110 to fill the opening 115. The lower electrode layer may be formed using a metal or a metal compound. For example, the lower electrode layer may be formed using tungsten, aluminum, copper, tantalum, titanium, molybdenum, niobium, zirconium, aluminum nitride, titanium aluminum nitride, titanium nitride, tungsten nitride, tantalum nitride, molybdenum nitride, molybdenum titanium nitride, molybdenum aluminum nitride, niobium nitride, titanium boron nitride, tungsten boron nitride, zirconium aluminum nitride, tantalum aluminum nitride, zirconium silicon nitride, tantalum silicon nitride, molybdenum silicon nitride, tungsten silicon nitride, titanium silicon nitride, etc. These materials may be used alone or in a combination thereof. The lower electrode layer may be formed by an atomic layer deposition (ALD) process, a CVD process, a sputtering process, a cyclic CVD process, an electron beam deposition (EBD) process, etc. An upper portion of the lower electrode layer is removed until the insulating structure 110 is exposed, thereby forming the lower electrode 120 that fills the opening 115. The lower electrode 120 may be formed by a chemical mechanical polishing (CMP) process, an etch-back process, or a combination of processes thereof.

In exemplary embodiments, the lower electrode 120 is formed to have a multi-layered structure including a metal layer, a metal nitride layer and/or a metal silicon nitride layer. In exemplary embodiments, the lower electrode 120 is formed to have a three-dimensional shape such as a cylinder, a polygonal pillar having an empty central portion, a cup, etc. In certain embodiments, the lower electrode layer is formed on the insulating structure 110 and does not completely fill the opening 115. A filling layer is formed on the lower electrode layer to fill the remaining portion of the opening 115 using an oxide (such as silicon oxide) or a nitride (such as silicon nitride). Upper portions of the filling layer and the lower electrode layer are removed, thereby forming the lower electrode 120 in the opening 115.

Referring to FIG. 5C, a phase-change material layer 150, a transition metal layer 160 and an upper electrode layer 170 are sequentially formed on the lower electrode 120 and the insulating structure 110. The phase-change material layer 150 may be formed by a physical vapor deposition (PVD) process using a chalcogenide. In exemplary embodiments, the phase-change material layer 150 is formed on the lower electrode 120 and the insulating structure 110 by a sputtering process using one target. For example, the phase-change material layer 150 may be formed using one chalcogenide target including GST doped with carbon and metal, or one chalcogenide target including GST doped with carbon, nitrogen and metal. More particularly, the phase-change material layer 150 may be formed using a chalcogenide target having any one of formulas (1) to (4). Furthermore, the phase-change material layer 150 may be formed on the lower electrode 120 and the insulating structure 110 using one target under an atmosphere of nitrogen. In other exemplary embodiments, the phase-change material layer 150 is formed on the lower electrode 120 and the insulating structure 110 by a co-sputtering process in which more than one target is simultaneously used. For example, the phase-change material layer 150 may be formed by a co-sputtering process using a first target including carbon or a metal carbide and a second target including GST. Furthermore, the phase-change material layer 150 may be formed by a co-sputtering process using the first target including carbon or a metal carbide and a second target including GST under an atmosphere of nitrogen.

The first transition metal layer 160 may be formed using a transition metal. For example, the first transition metal layer 160 may be formed using titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), platinum (Pt), etc. These metals may be used alone or in a combination thereof. The first transition metal layer 160 may be formed by an ALD process, a CVD process, a sputtering process, a cyclic CVD process, an EBD process, etc. In exemplary embodiments, the first transition metal layer 160 is formed to have a thickness of about 20 to about 100 Å.

The upper electrode layer 170 may be formed using a metal nitride. For exemplary, the upper electrode layer 170 may be formed using titanium nitride, titanium aluminum nitride, tantalum nitride, tungsten nitride or molybdenum nitride, etc. These materials may be used alone or in a combination thereof. The upper electrode layer 170 may be formed by an ALD process, a CVD process, a sputtering process, a cyclic CVD process, an EBD process, etc. In exemplary embodiments, the upper electrode layer 170 is formed to have a thickness of about 200 to about 800 Å.

Referring to FIG. 5D, after forming a second photoresist pattern (not shown) on the upper electrode layer 170, the upper electrode layer 170, the first transition metal layer 160 and the phase-change material layer 150 are partially removed using the second photoresist pattern as an etching mask, thereby forming a phase-change material layer pattern 152, a first transition metal layer pattern 162 and an upper electrode 172 sequentially stacked on the lower electrode 120 and the insulating structure 110. Thus, the phase-change memory unit in accordance with some exemplary embodiments may be completed.

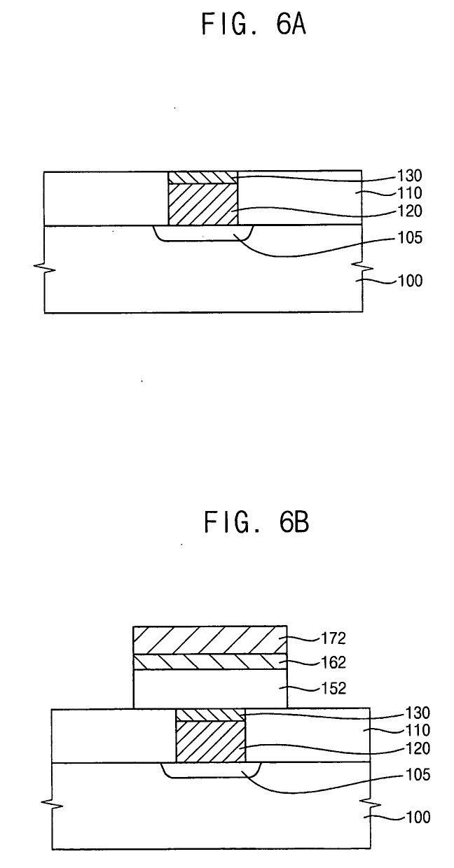

FIGS. 6A and 6B are cross-sectional views illustrating a method of forming a phase-change memory unit in accordance with other exemplary embodiments. The method of forming the phase-change memory unit illustrated with reference to FIGS. 6A and 6B are substantially the same as or similar to that of FIGS. 5B to 5D, respectively, except that a second transition metal layer pattern is further formed between a lower electrode and a phase-change material layer pattern and the lower electrode may include other materials. Like numerals refer to like elements, and detailed explanations about the like elements are omitted here for the purpose of brevity.

Referring to FIG. 6A, after forming an impurity region 105 at an upper portion of a substrate 100, an insulating structure 110 is formed on the substrate 100 to cover the impurity region 105. After forming an opening (not shown) that exposes the impurity region 105, a lower electrode layer is formed on the insulating structure 110 to fill the opening.

The lower electrode layer may be formed using a metal nitride such as titanium nitride, titanium aluminum nitride, tantalum nitride, tungsten nitride, molybdenum nitride, etc. These materials may be used alone or in a combination thereof. The lower electrode layer may be formed by an ALD process, a CVD process, a sputtering process, a cyclic CVD process, an EBD process, etc. An upper portion of the lower electrode layer is removed, thereby forming a lower electrode 120 that partially fills the opening.

A second transition metal layer is formed on the insulating structure 110 to fill the remaining portion of the opening. The second transition metal layer is formed using a transition metal. For example, the second transition metal layer may be formed using titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), platinum (Pt), etc. These metals may be used alone or in a combination thereof. The second transition metal layer may be formed by an ALD process, a CVD process, a sputtering process, a cyclic CVD process, an EBD process, etc. In exemplary embodiments, the second transition metal layer is formed to have a thickness of no more than about 15 Å.

An upper portion of the second transition metal layer is removed until the insulating structure 110 is exposed, thereby forming a second transition metal layer pattern 130 that fills the remaining portion of the opening.

Referring to FIG. 6B, after forming a phase-change material layer, a transition metal layer and an upper electrode layer on the second transition metal layer pattern 130 and the insulating structure 110, the upper electrode layer, the transition metal layer and the phase-change material layer are patterned to form a phase-change material layer pattern 152, a first transition metal layer pattern 162 and an upper electrode 172 sequentially stacked on the second transition metal layer pattern 130 and the insulating structure 110. Thus, the phase-change memory unit may be completed.

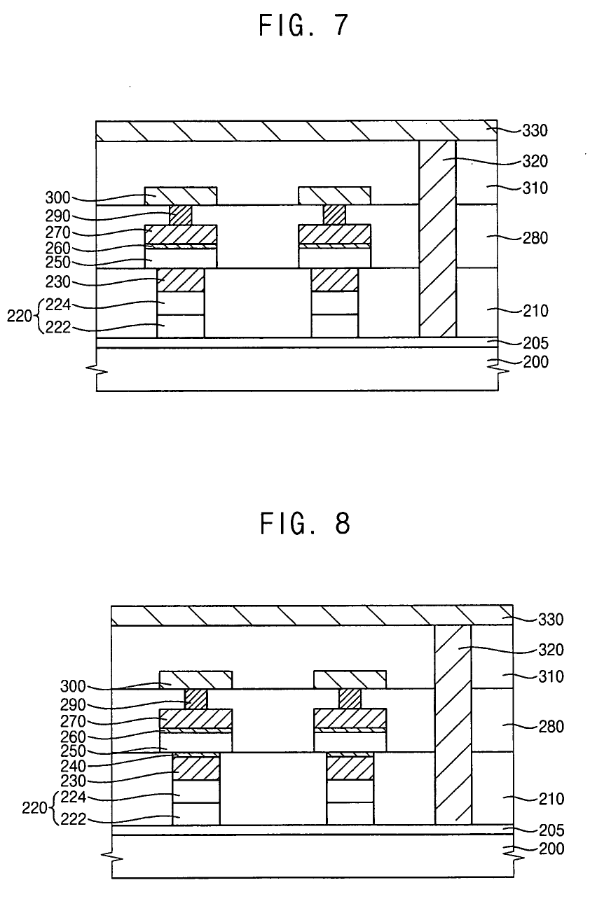

FIG. 7 is a cross-sectional view illustrating a phase-change memory device in accordance with some exemplary embodiments. In FIG. 7, a phase-change memory unit included in the phase-change memory device is substantially the same as or similar to that of FIG. 1. Thus, detailed explanations about like elements are omitted here for the purpose of brevity.

Referring to FIG. 7, the phase-change memory device includes a substrate 200, a lower structure, a first insulating interlayer 210, a conductive structure, a lower electrode 230, a phase-change material layer pattern 250, a first transition metal layer pattern 260, an upper electrode 270, a second insulating interlayer 280, a first wiring 300, a third insulating interlayer 310 and a second wiring 330.

The substrate 200 may include a semiconductor substrate, and an isolation layer (not shown) may be formed on the substrate 200 to define an active region and a field region in the substrate 200. For example, the substrate 200 may include a silicon substrate, a germanium substrate, a silicon-germanium substrate, a SOI substrate, a GOI substrate, etc. The lower structure may be formed in or on the substrate 200, and include an impurity region 205.

The first insulating interlayer 210 is formed on the substrate 200 to cover the lower structure. The first insulating interlayer 210 may include an oxide, a nitride and/or an oxynitride. The first insulating interlayer 210 may have an opening (not shown) that exposes the impurity region 205.

The conductive structure partially fills the opening. In exemplary embodiments, the conductive structure includes a diode 220. The diode 220 includes a first conductive layer 222 and a second conductive layer 224. The first and second conductive layers 222 and 224 may include silicon doped with impurities. The first conductive layer 222 may include impurities having a conductivity type substantially the same as that of the impurities of the impurity region 205, and the second conductive layer 224 may include impurities having a conductivity type different from that of the impurities of the first conductive layer 222. An ohmic layer (not shown) may be further formed on the diode 220. The ohmic layer may include a metal silicide.

The lower electrode 230 is formed on the conductive structure to fill the remaining portion of the opening. The phase-change material layer pattern 250, the first transition metal layer pattern 260 and the upper electrode 270 are formed on the lower electrode 230 and the first insulating interlayer 210. Alternatively, the phase-change material layer pattern 250, the first transition metal layer pattern 260 and the upper electrode 270 may be formed only on the lower electrode 230. The lower electrode 230, the phase-change material layer pattern 250, the first transition metal layer pattern 260 and the upper electrode 270 may constitute the phase-change memory unit, and be substantially the same as that of FIG. 1.

The second insulating interlayer 280 is formed on the first insulating interlayer 210 to cover the upper electrode 270, the first transition metal layer pattern 260 and the phase-change material layer pattern 250. The second insulating interlayer 280 may include an oxide, a nitride and/or an oxynitride. The first and second insulating interlayers 210 and 280 may include substantially the same material or different materials.

The upper electrode 270 is electrically connected to the first wiring 300 via a first plug 290 in the second insulating interlayer 280. The first plug 290 and the first wiring 300 may include a metal and/or a metal nitride. The first wiring 300 may include a bit line.

The third insulating interlayer 310 is formed on the second insulating interlayer 280 to cover the first wiring 300. The third insulating interlayer 310 may include an oxide, a nitride and/or an oxynitride. The first, second and third insulating interlayers 210, 280 and 310 may include substantially the same material or different materials.

The second wiring 330 is formed on the third insulating interlayer 310 and is electrically connected to the substrate 200 via a second plug 320. The second wiring 330 may include a word line.

The phase-change memory device illustrated with reference to FIG. 7 has the first transition metal layer pattern 260 between the phase-change material layer pattern 250 including GST and carbon, and the upper electrode 270 including a metal nitride. This phase-change memory device is different from other phase-change memory devices having an upper electrode including a metal on a phase-change material layer pattern. Thus, in the phase-change memory device in accordance with some exemplary embodiments, the amount of the metal of the upper electrode 270 diffusing into the phase-change material layer pattern 250 decreases, so a power consumption may decrease because reset current does not increase, and a sensing margin may increase because a reset resistance does not decrease. As a result, the phase-change memory device in accordance with some exemplary embodiments may have good electrical characteristics.

Additionally, the phase-change material layer pattern 250 may include carbon, however, the phase-change material layer pattern 250 need not include an amount of carbon (e.g., more than about 12% by weight of carbon based on the total weight thereof) such that the phase-change memory device has a large set resistance, because the phase-change memory device in accordance with some exemplary embodiments has the first transition metal layer pattern 260. Thus, the phase-change memory device may have good data retention.

FIG. 8 is a cross-sectional view illustrating a phase-change memory device in accordance with other exemplary embodiments. A phase-change memory unit in the phase-change memory device illustrated with reference to FIG. 8 is substantially the same as or similar to that of FIG. 2. Additionally, the phase-change memory device illustrated with reference to FIG. 8 is substantially the same as or similar to that of FIG. 7, except that a second transition metal layer pattern is formed between a lower electrode and a phase-change material layer pattern and the lower electrode may include other materials. Like numerals refer to like elements, and detailed explanations about the like elements are omitted here for the purpose of brevity.

Referring to FIG. 8, the phase-change memory device includes a substrate 200, a lower structure, a first insulating interlayer 210, a conductive structure, a lower electrode 230, a second transition metal layer pattern 240, a phase-change material layer pattern 250, a first transition metal layer pattern 260, an upper electrode 270, a second insulating interlayer 280, a first wiring 300, a third insulating interlayer 310 and a second wiring 330.

The lower electrode 230 includes a metal nitride. The second transition metal layer pattern 240 includes a transition metal. In exemplary embodiments, the second transition metal layer pattern 250 has a thickness of no more than about 15 Å.

The phase-change memory device illustrated with reference to FIG. 8 has not only the first transition metal layer pattern 260 between the phase-change material layer pattern 250 including GST and carbon, but also the second transition metal layer pattern 240 between the lower electrode 230 and the phase-change material layer pattern 250. Thus, the phase-change memory device can have good data retention characteristics and set resistance distribution characteristics.

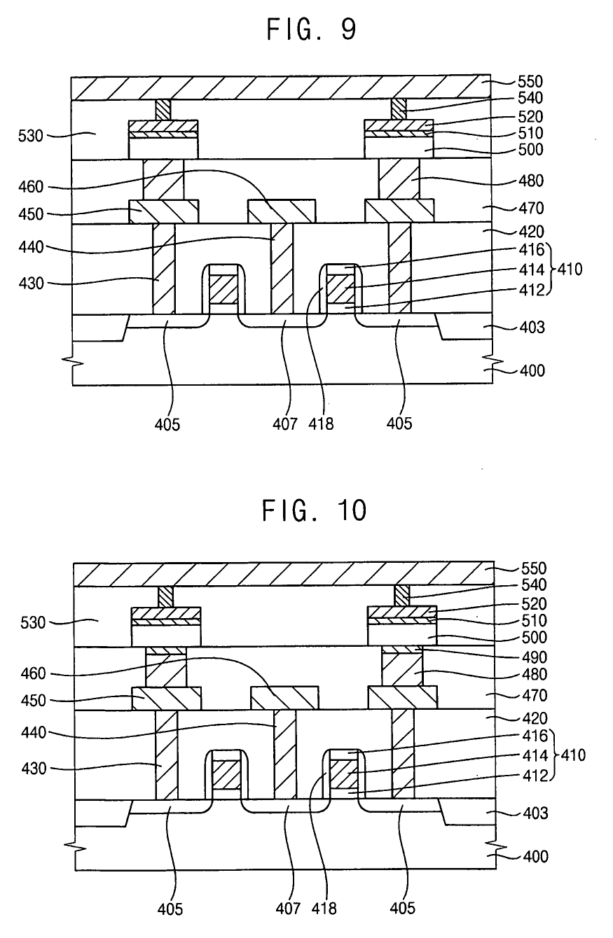

FIG. 9 is a cross-sectional view illustrating a phase-change memory device in accordance with still other exemplary embodiments. A phase-change memory unit included in the phase-change memory device illustrated with reference to FIG. 9 is substantially the same as or similar to that of FIG. 1. Detailed explanations about the like elements are omitted here for the purpose of brevity.

Referring to FIG. 9, the phase-change memory device includes a transistor having a gate structure 410 and impurity regions 405 and 407, a lower electrode 480, a phase-change material layer pattern 500, a first transition metal layer pattern 510, an upper electrode 520, and wirings 460 and 550.

The gate structure 410 is formed on the substrate 400. The substrate 400 is divided into an active region and a field region by an isolation layer 403, and the gate structure 410 is formed on the active region. The isolation layer 403 may include silicon oxide. The gate structure 410 includes a gate insulation layer pattern 412, a gate electrode 414 and a gate mask 416 sequentially stacked on the active region. The gate structure 410 further includes a gate spacer 416. The gate insulation layer pattern 412 may include silicon oxide or a metal oxide, and the gate electrode 414 may include doped polysilicon, a metal and/or a metal silicide. The gate mask 416 and the gate spacer 418 may include silicon nitride or silicon oxynitride.

The first and second impurity regions 405 and 407 are formed at upper portions of the active region between the gate structures 410. For example, the first and second impurity regions 405 and 407 may serve as a source region and a drain region, respectively.

A first insulating interlayer 420 is formed on the substrate 400 to cover the gate structure 410. The first insulating interlayer 420 may include USG, SOG, FOX, BPSG, PSG, TEOS, PE-TEOS, HDP-CVD oxide, etc. A first opening (not shown) and a second opening (not shown) are formed through the first insulating interlayer 420 to expose the first and second impurity regions 405 and 407, respectively. A first contact 430 and a second contact 440 are formed on the first and second impurity regions 405 and 407 to fill the first and second openings, respectively. The first and second contacts 430 and 440 may include a metal, a metal nitride or doped polysilicon. For example, the first and second contacts 430 and 440 may include tungsten, aluminum, titanium, copper, tantalum, tungsten nitride, titanium nitride, aluminum nitride, titanium aluminum nitride, tantalum nitride, etc.

A pad 450 is formed on the first contact 430 and the first insulating interlayer 420. The first wiring 460 is formed on the second contact 440 and the first insulating interlayer 420. The first wiring 460 may include a bit line. The pad 450 and the first wiring 460 may include substantially the same material. The pad 450 and the first wiring 460 may include a metal, a metal nitride or doped polysilicon. For example, the pad 450 and the first wiring 460 may include tungsten, aluminum, copper, tantalum, titanium, molybdenum, niobium, zirconium, aluminum nitride, titanium aluminum nitride, titanium nitride, tungsten nitride, tantalum nitride, molybdenum nitride, molybdenum titanium nitride, molybdenum aluminum nitride, niobium nitride, titanium boron nitride, tungsten boron nitride, zirconium aluminum nitride, tantalum aluminum nitride, zirconium silicon nitride, tantalum silicon nitride, molybdenum silicon nitride, tungsten silicon nitride, titanium silicon nitride, etc. These metals may be used alone or in a combination thereof.

A second insulating interlayer 470 is formed on the first insulating interlayer 420 to cover the pad 450 and the first wiring 460. The second insulating interlayer 470 may include USG, SOG, FOX, BPSG, PSG, TEOS, PE-TEOS, HDP-CVD oxide, etc. The second insulating interlayer 470 has a third opening (not shown) exposing the pad 450 therein.

The lower electrode 480 is formed on the pad 450 to fill the third opening. The phase-change material layer pattern 500, the first transition metal layer pattern 510 and the upper electrode 520 are formed on the lower electrode 480 and the second insulating interlayer 470. Alternatively, the phase-change material layer pattern 500, the first transition metal layer pattern 510 and the upper electrode 520 may be formed only on the lower electrode 480. The lower electrode 480, the phase-change material layer pattern 500, the first transition metal layer pattern 510 and the upper electrode 520 may constitute the phase-change memory unit, and are substantially the same as or similar to those of FIG. 1.

A third insulating interlayer 530 is formed on the second insulating interlayer 470 to cover the upper electrode 520, the first transition metal layer pattern 510 and the phase-change material layer pattern 500. The third insulating interlayer 530 may include an oxide, a nitride and/or an oxynitride.

The upper electrode 520 is electrically connected to the second wiring 550 via a plug 540 in the third insulating interlayer 530. The plug 540 and the second wiring 550 may include a metal and/or a metal nitride.

FIG. 10 is a cross-sectional view illustrating a phase-change memory device in accordance with other exemplary embodiments. A phase-change memory unit included in the phase-change memory device illustrated with reference to FIG. 10 is substantially the same as or similar to that of FIG. 2. Additionally, the phase-change memory device illustrated with reference to FIG. 10 is substantially the same as or similar to that of FIG. 9, except that a second transition metal layer pattern is formed between a lower electrode and a phase-change material layer pattern and the lower electrode may include other materials. Like numerals refer to like elements, and detailed explanations about the like elements are omitted here for the purpose of brevity.

Referring to FIG. 10, the phase-change memory device includes a transistor having a gate structure 410 and impurity regions 405 and 407, a lower electrode 480, a second transition metal layer pattern 490, a phase-change material layer pattern 500, a first transition metal layer pattern 510, an upper electrode 520, and wirings 460 and 550.

The lower electrode 480 includes a metal nitride. The second transition metal layer pattern 490 includes a transition metal. In exemplary embodiments, the second transition metal layer pattern 490 has a thickness of no more than about 15 Å.

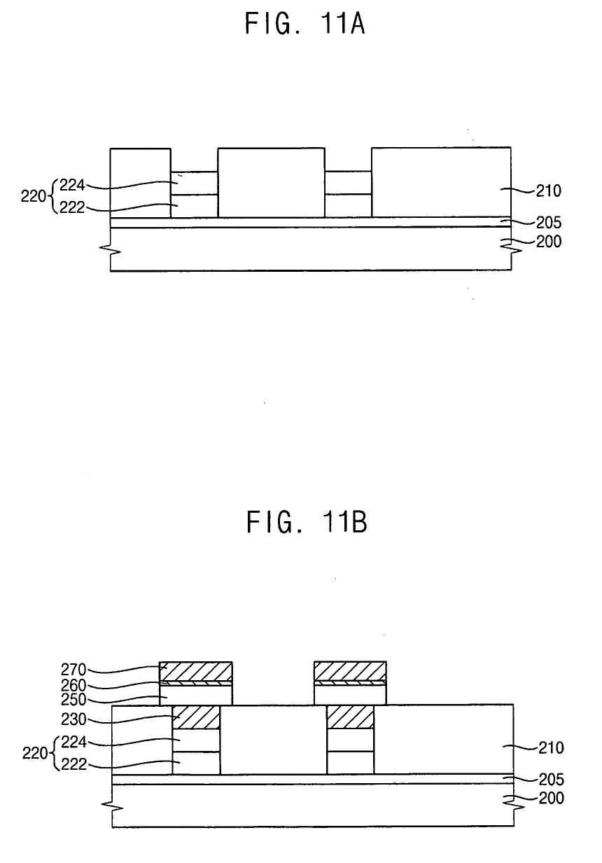

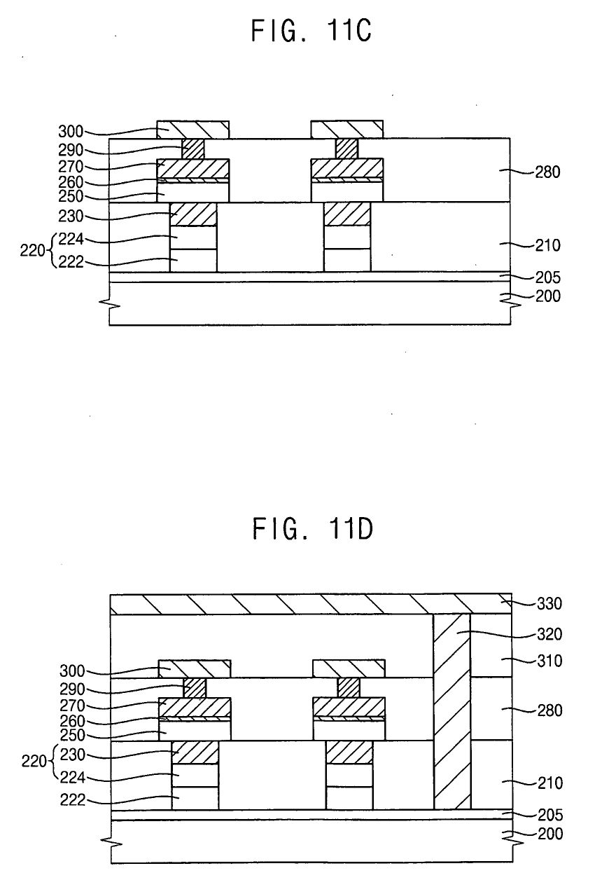

FIGS. 11A to 11D are cross-sectional views illustrating a method of manufacturing a phase-change memory device in accordance with some exemplary embodiments. Although a method of manufacturing the phase-change memory device in FIG. 7 is illustrated with reference to FIGS. 11A to 11D, exemplary embodiments illustrated with reference to FIGS. 11A to 11D are not restricted to the above device. Additionally, in FIGS. 11A to 11D, a method of forming a phase-change memory unit included in the phase-change memory device is substantially the same as or similar to that of FIGS. 5A to 5D, so detailed explanations about like elements are omitted here for the purpose of brevity.

Referring to FIG. 11A, impurities are implanted onto a portion of a substrate 200 to form an impurity region 205. The impurity region 205 may be formed by an ion implantation process. A first insulating interlayer 210 is formed on the substrate 200 to cover the impurity region 205. The first insulating interlayer 210 may be formed using an oxide, a nitride and/or an oxynitride. The first insulating interlayer 210 is partially removed by a photolithography process to form a first opening (not shown) that exposes the impurity region 205 through the first insulating interlayer 210. A first conductive layer is formed on the first insulating interlayer 210 using a metal or a metal compound to fill the first opening. An upper portion of the first conductive layer is removed to form a first conductive layer pattern partially filling the first opening, and impurities are implanted into the first conductive layer pattern to form a first conductive sublayer 222 and a second conductive sublayer 224 at a lower portion of the opening. Thus, a diode 220 is formed to partially fill the first opening.

Referring to FIG. 11B, a lower electrode layer is formed on the first insulating interlayer 210 to fill the remaining portion of the first opening. The lower electrode layer may be formed using a metal or a metal compound. An upper portion of the lower electrode layer is removed until the first insulating interlayer 210 is exposed, thereby forming a lower electrode 230 that fills the remaining portion of the first opening. A phase-change material layer including carbon and GST, a transition metal layer including a transition metal, and an upper electrode layer including a metal nitride are sequentially formed on the lower electrode 230 and the first insulating interlayer 210. The upper electrode layer, the first transition metal layer and the phase-change material layer are partially etched to form a phase-change material layer pattern 250, a first transition metal layer pattern 260 and an upper electrode 270 sequentially stacked on the lower electrode 230 and the first insulating interlayer 210.

Referring to FIG. 11C, a second insulating interlayer 280 is formed on the first insulating interlayer 210 to cover the upper electrode 270, the first transition metal layer pattern 260 and the phase-change material layer pattern 250. The second insulating interlayer 280 may be formed using an oxide, a nitride and/or an oxynitride. The second insulating interlayer 280 is partially removed by a photolithography process to form a second opening (not shown) that exposes the upper electrode 270 therein. A second conductive layer is formed on the second insulating interlayer 280 to fill the second opening. The second conductive layer may be formed using a metal and/or a metal nitride. An upper portion of the second conductive layer is removed until the second insulating interlayer 280 is exposed, thereby forming a first plug 290 that fills the second opening. A third conductive layer is formed on the first plug 290 and the second insulating interlayer 280 using a metal and/or a metal nitride. The third conductive layer is patterned by a photolithography process to form a first wiring 300 connected to the first plug 290.

Referring to FIG. 1D, a third insulating interlayer 310 is formed on the second insulating interlayer 280 to cover the first wiring 300. The third insulating interlayer 310 may be formed using an oxide, a nitride and/or an oxynitride. The third insulating interlayer 310, the second insulating interlayer 280 and the first insulating interlayer 210 are partially removed by a photolithography process to form a third opening (not shown) that exposes the impurity region 205. A fourth conductive layer is formed on the third insulating interlayer 310 to fill the third opening. The fourth conductive layer may be formed using a metal and/or a metal nitride. An upper portion of the fourth conductive layer is removed until the third insulating interlayer 310 is exposed, thereby forming a second plug 320 that fills the second opening. A second wiring 330 is formed on the second plug 320 and the third insulating interlayer 310 using a metal and/or a metal nitride. Thus, the phase-change memory device in accordance with some exemplary embodiments is completed.

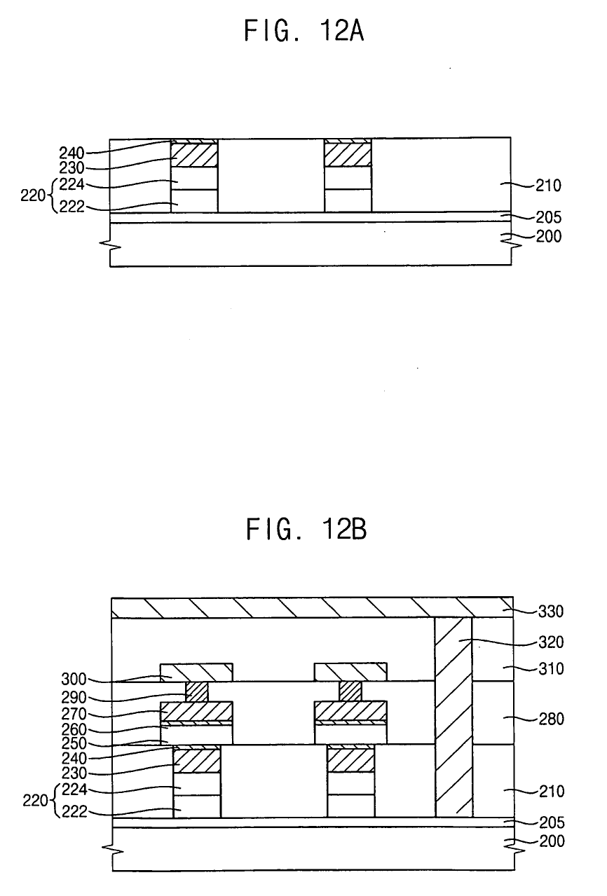

FIGS. 12A to 12B are cross-sectional views illustrating a method of manufacturing a phase-change memory device in accordance with other exemplary embodiments. In FIGS. 12A to 12B, a method of forming a phase-change memory unit included in the phase-change memory device is substantially the same as or similar to that of FIGS. 6A to 6B. Additionally, the method of forming the phase-change memory device illustrated with reference to FIGS. 12A to 12B is substantially the same as or similar to that of FIGS. 11A to 11D, except that a second transition metal layer pattern is formed between a lower electrode and a phase-change material layer pattern and the lower electrode may include other materials. Like numerals refer to like elements, and detailed explanations about the like elements are omitted here for the purpose of brevity.

Referring to FIG. 12A, after forming an impurity region 205 on a substrate 200, a first insulating interlayer 210 is formed on the substrate 200. After forming an opening (not shown) that exposes the impurity region 205 through the first insulating interlayer 210, a diode 220 is formed on the impurity region 205 to partially fill the opening. After forming a lower electrode 230 on the diode 220 using a metal nitride, a second transition metal layer pattern 240 is formed on the lower electrode 230.

Referring to FIG. 12B, a phase-change material layer pattern 250, a first transition metal layer pattern 260, and an upper electrode 270 are formed on the second transition metal layer pattern 240 and the first insulating interlayer 210. A second insulating interlayer 280 is formed on the first insulating interlayer 210 to cover the upper electrode 270, the first transition metal layer pattern 260 and the phase-change material layer pattern 250. A first plug 290 and a first wiring 300 are formed through the second insulating interlayer 280 to electrically connect to the upper electrode 270. A third insulating interlayer 310 is formed on the second insulating interlayer 280 to cover the first wiring 300, and a second plug 320 and a second wiring 330 are formed to connect to the impurity region 205, thereby completing the phase-change memory device.

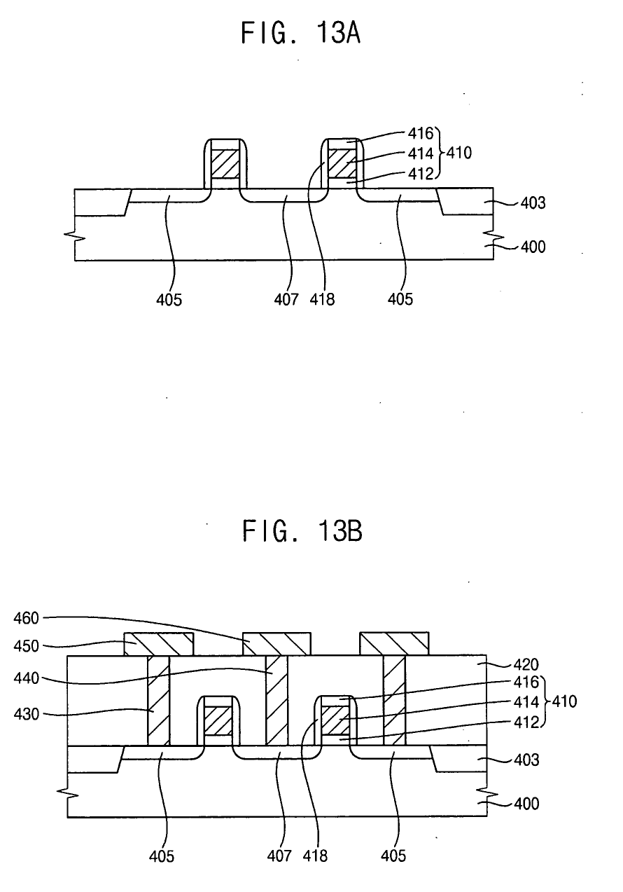

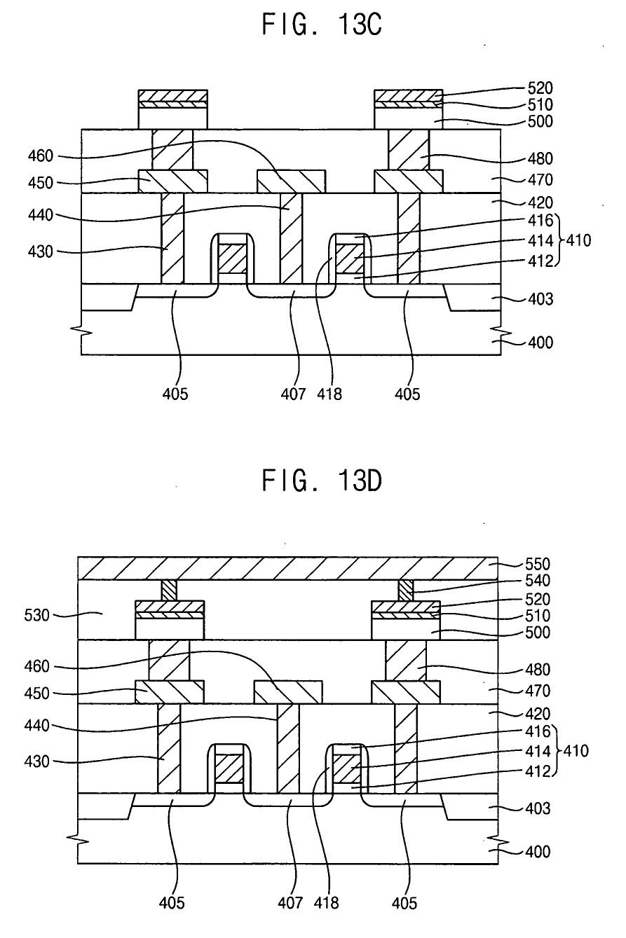

FIGS. 13A to 13D are cross-sectional views illustrating a method of manufacturing a phase-change memory device in accordance with still other exemplary embodiments. Although a method of manufacturing the phase-change memory device in FIG. 9 is illustrated with reference to FIGS. 13A to 13D, exemplary embodiments illustrated with reference to FIGS. 13A to 13D are not restricted to the above device. Additionally, in FIGS. 13A to 13D, a method of forming a phase-change memory unit included in the phase-change memory device is substantially the same as or similar to that of FIGS. 5A to 5D. Detailed explanations about the like elements are omitted here for the purpose of brevity.

Referring to FIG. 13A, an isolation layer 403 is formed on a substrate 400 by an isolation process, thereby defining an active region and a field region in the substrate 400. The substrate 400 may include a semiconductor substrate, and the isolation layer 403 may be formed by a STI process or a thermal oxidation process. After forming a gate insulation layer, a gate conductive layer, and a gate mask layer on the substrate 400, the gate mask layer, the gate conductive layer and the gate insulation layer are patterned to form a gate structure 410 on the active region. The gate structure 410 may include a gate insulation layer pattern 412, a gate electrode 414 and a gate mask 416. After forming a nitride layer on the substrate 400 that covers the gate structure 410, the nitride layer is partially etched by an anisotropic etching process, thereby forming a gate spacer 418 on a sidewall of the gate structure 410.

First and second impurity regions 405 and 407 are formed at upper portions of the active region adjacent to the gate structure 410 by an ion implantation process using the gate structure 410 as an etching mask. Thus, a transistor including the gate structure 410 and the impurity regions 405 and 407 may be formed on the substrate 400.

Referring to FIG. 13B, a first insulating interlayer 420 is formed on the substrate 400 to cover the transistor. The first insulating interlayer 420 may be formed using an oxide, a nitride and/or an oxynitride. The first insulating interlayer 420 may be formed by a CVD process, a LPCVD process, a PECVD process, an ALD process, a HDP-CVD process, etc. The first insulating interlayer 420 is partially removed to form first and second openings (not shown) therethrough, and a first conductive layer is formed on the first insulating interlayer 420 to fill the first and second openings. The first conductive layer may be formed using a metal and/or a metal nitride. The first conductive layer may be formed by a CVD process, a sputtering process, an ALD process, an EBD process, a pulse laser deposition (PLD) process, etc. An upper portion of the first conductive layer is removed until the first insulating interlayer 420 is exposed, thereby forming first and second contacts 430 and 440 that fill the first and second openings, respectively. The first and second contacts 430 and 440 may be formed on the first and second impurity regions 405 and 407, respectively. The first and second contacts 430 and 440 may be formed by a CMP process and/or an etch-back process.

A second conductive layer is formed on the first and second contacts 430 and 440 and the first insulating interlayer 420 using doped polysilicon, a metal and/or a metal nitride. The second conductive layer may be formed by a CVD process, a sputtering process, an ALD process, an EBD process, a PLD process, etc. The second conductive layer is patterned to form a pad 450 and a first wiring 460 on the first and second contacts 430 and 440, respectively. The first wiring 460 may include a bit line.

Referring to FIG. 13C, a second insulating interlayer 470 is formed on the first insulating interlayer 420 to cover the pad 450 and the first wiring 460. The second insulating interlayer 470 may be formed using an oxide, a nitride and/or an oxynitride. The second insulating interlayer 470 may be formed on the first insulating interlayer 420 by a CVD process, a LPCVD process, a PECVD process, an ALD process, a HDP-CVD process, etc. The second insulating interlayer 470 is partially etched to form a third opening (not shown) that exposes the pad 450 therein. A lower conductive layer is formed on the exposed pad 450, a sidewall of the third opening and the second insulating interlayer 470. The lower conductive layer may be formed using a metal or a metal nitride. An upper portion of the lower conductive layer is removed until the second insulating interlayer 470 is exposed to form a lower electrode 480 that fills the third opening.

A phase-change material layer pattern 500, a first transition metal layer pattern 510 and an upper electrode 520 are formed on the lower electrode 480 and the second insulating interlayer 470.

Referring to FIG. 13D, a third insulating interlayer 530 is formed on the second insulating interlayer 470 to cover the upper electrode 520, the first transition metal layer pattern 510 and the phase-change material layer pattern 500, and a fourth opening (not shown) that exposes the upper electrode 520 is formed therein. A third conductive layer is formed on the third insulating interlayer 530 using doped polysilicon, a metal or a metal nitride to fill the fourth opening. An upper portion of the third conductive layer is removed until the third insulating interlayer 530 is exposed, thereby forming a plug 540 that fills the fourth opening. A second wiring 550 is formed on the plug 540 and the third insulating interlayer 530 using doped polysilicon, a metal or a metal nitride, thereby completing the phase-change memory device.

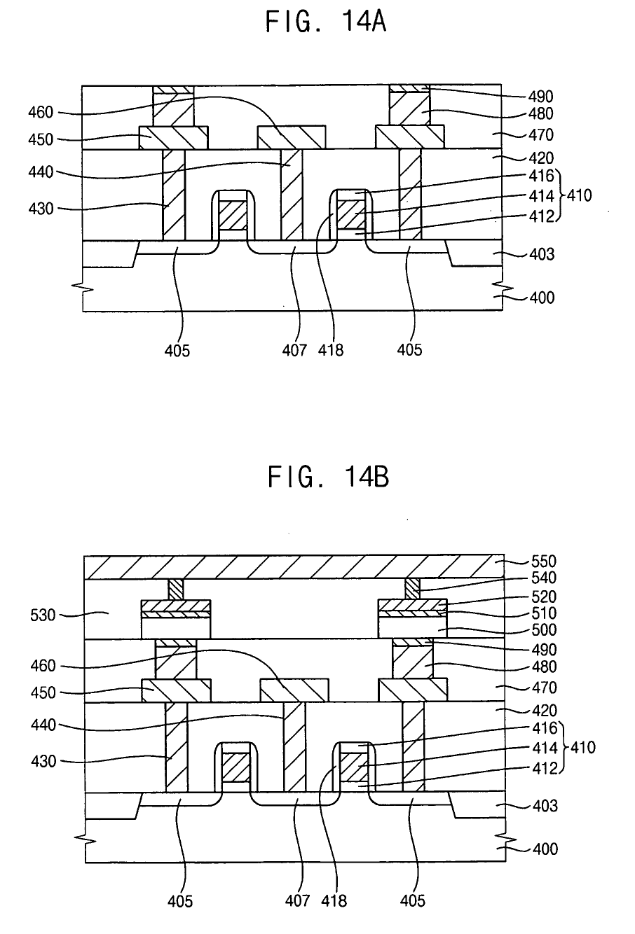

FIGS. 14A and 14B are cross-sectional views illustrating a method of manufacturing a phase-change memory device in accordance with other exemplary embodiments. In FIGS. 14A and 14B, a method of forming a phase-change memory unit included in the phase-change memory device is substantially the same as or similar to that of FIGS. 6A to 6B. Additionally, the method of forming the phase-change memory device illustrated with reference to FIGS. 14A to 14B is substantially the same as or similar to that of FIGS. 13A to 13D, except that a second transition metal layer pattern is formed between a lower electrode and a phase-change material layer pattern and the lower electrode may include other materials. Like numerals refer to like elements, and detailed explanations about the like elements are omitted here for the purpose of brevity.

Referring to FIG. 14A, after forming an isolation layer 403 on a substrate 400, a gate structure 410 is formed on the substrate 400. First and second impurity regions 405 and 407 are formed at upper portions of the substrate 400 by an ion implantation process, and a gate spacer 418 may be formed on a sidewall of the gate structure 410. A first insulating interlayer 420 is formed on the substrate 400 to cover the gate structure 410 and the gate spacer 418, and first and second contacts 430 and 440 electrically connected to the first and second impurity regions 405 and 407, respectively, are formed through the first insulating interlayer 420. A pad 450 electrically connected to the first contact 430 and a first wiring 460 electrically connected to the second contact 440 are formed, and a second insulating interlayer 470 is formed on the first insulating interlayer 420 to cover the pad and the first wiring 460. A lower electrode 480 and a second transition metal layer pattern 490, which is electrically connected to the pad, are formed in the second insulating interlayer 470.

Referring to FIG. 14B, a phase-change material layer pattern 500, a first transition metal layer pattern 510 and an upper electrode 520 are formed on the second transition metal layer pattern 490 and the second insulating interlayer 470. A third insulating interlayer 530 is formed on the second insulating interlayer 470 to cover the phase-change material layer pattern 500, the first transition metal layer pattern 510 and the upper electrode 520. A plug 540 is formed through the third insulating interlayer 530 to electrically connect to the upper electrode 520, and a second wiring 550 is formed on the third insulating interlayer 530 to electrically connect to the plug 540, thereby completing the phase-change memory device.

According to some exemplary embodiments, the phase-change memory device has a transition metal layer pattern between a phase-change material layer pattern including GST and carbon, and an upper electrode including a metal nitride. Thus, the amount of metal included in the upper electrode diffusing into the phase-change material layer pattern may decrease, so that power consumption may decrease because of a decrease in a reset current, and a sensing margin may not decrease because reset resistance does not decrease. Additionally, even though the phase-change material layer pattern has a relatively low concentration of carbon, the phase-change memory device may have good data retention and good endurance due to the transition metal layer pattern.

The foregoing is illustrative of exemplary embodiments and is not to be construed as limiting. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses, if any, are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A phase-change memory unit comprising:
a lower electrode on a substrate;
a phase-change material layer pattern on the lower electrode, the phase-change material layer pattern including germanium-antimony-tellurium (GST) and carbon;
a first transition metal layer pattern on the phase-change material layer pattern; and
an upper electrode on the first transition metal layer pattern.

2. The phase-change memory unit of claim 1, wherein the first transition metal layer pattern comprises at least one selected from the group consisting of titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

3. The phase-change memory unit of claim 1, wherein the first transition metal layer pattern has a thickness of about 20 to about 100 Å.

4. The phase-change memory unit of claim 1, wherein the upper electrode comprises a metal nitride.

5. The phase-change memory unit of claim 4, wherein the upper electrode comprises at least one selected from the group consisting of titanium nitride, titanium aluminum nitride, tantalum nitride, tungsten nitride, and molybdenum nitride.

6. The phase-change memory unit of claim 1, wherein the phase-change material layer pattern has formula (1),
C_{A}M_{B}[Ge_{X}Sb_{Y}Te_{(100-X-Y)}]_{(100-A-B)} (1)
wherein C represents carbon, and M represents metal,
and wherein A, B, X and Y satisfy inequalities 0.2≦A≦25.0, 0.0≦B≦10.0, 0.1≦X≦30.0, and 0.1≦Y≦90.0.

7. The phase-change memory unit of claim 6, wherein the metal represented by M comprises at least one selected from the group consisting of aluminum (Al), gallium (Ga), indium (In), titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

8. The phase-change memory unit of claim 1, wherein the phase-change material layer pattern has formula (2),
C_{A}M_{B}[Ge_{X}Z₍₁₀₀₋ₓ₎Sb_{Y}Te_{(100-X-Y)}]_{(100-A-B)} (2)
wherein Z represents silicon or tin,
and wherein A, B, X and Y satisfy inequalities 0.2≦A≦25.0, 0.0≦B≦10.0, 0.1≦X≦80.0, and 0.1≦Y≦90.0.

9. The phase-change memory unit of claim 1, wherein the phase-change material layer pattern has formula (3),
C_{A}M_{B}[Ge_{X}Sb_{Y}T_{(100-y)}Te_{(100-X-Y)}]_{(100-A-B)} (3)
wherein T represents arsenic or bismuth,
and wherein A, B, X and Y satisfy inequalities 0.2≦A≦25.0, 0.0≦B≦10.0, 0.1≦X≦90.0, and 0.1≦Y≦80.0.

10. The phase-change memory unit of claim 1, wherein the phase-change material layer pattern has formula (4),
C_{A}M_{B}[Ge_{X}Sb_{Y}Q_{(100-X-Y)}]_{(100-A-B)} (4)
wherein Q represents antimony and selenium,
and wherein A, B, X and Y satisfy inequalities 0.2≦A≦25.0, 0.0≦B≦10.0, 0.1≦X≦90.0, and 0.1≦Y≦90.0.

11. The phase-change memory unit of claim 1, wherein the phase-change memory material layer pattern further comprises nitrogen.

12. The phase-change memory unit of claim 1, wherein the lower electrode comprises a metal or a metal nitride.

13. The phase-change memory unit of claim 12, wherein the lower electrode comprises the metal nitride, and wherein the phase-change memory unit further comprises a second transition metal layer pattern between the lower electrode and the phase-change material layer pattern.

14. The phase-change memory unit of claim 13, wherein the second transition metal layer pattern comprises at least one selected from the group consisting of titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

15. The phase-change memory unit of claim 13, wherein the second transition metal layer pattern has a thickness of less than about 15 Å.

16. A method of forming a phase-change memory unit, the method comprising:
forming a lower electrode on a substrate;
forming a phase-change material layer pattern including GST and carbon on the lower electrode;
forming a first transition metal layer pattern on the phase-change material layer pattern; and
forming an upper electrode on the first transition metal layer pattern.

17. The method of claim 16, wherein the first transition metal layer pattern is formed using at least one selected from the group consisting of titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

18. The method of claim 16, wherein the first transition metal layer pattern is formed to have a thickness of about 20 to about 100 Å.

19. The method of claim 16, wherein the upper electrode is formed using a metal nitride.

20. The method of claim 16, wherein the phase-change material layer pattern has formula,
C_{A}M_{B}[Ge_{X}Sb_{Y}Te_{(100-X-Y)}]_{(100-A-B)}
wherein C represents carbon, and M represents metal,
and wherein A, B, X and Y satisfy inequalities 0.2≦A≦25.0, 0.0≦B≦10.0, 0.1≦X≦30.0, and 0.1≦Y≦90.0.

21. The method of claim 16, wherein the lower electrode is formed using a metal nitride, and the method further comprises forming a second transition metal layer pattern on the lower electrode.

22. A phase-change memory device comprising:
a switching element on a substrate;
a lower electrode electrically connected to the switching element;
a phase-change material layer pattern on the lower electrode, the phase-change material layer pattern including GST and carbon;
a first transition metal layer pattern on the phase-change material layer pattern; and
an upper electrode on the first transition metal layer pattern.

23. The phase-change memory device of claim 22, wherein the first transition metal layer pattern comprises at least one selected from the group consisting of titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

24. The phase-change memory device of claim 22, wherein the upper electrode comprises a metal nitride.

25. The phase-change memory device of claim 22, wherein the phase-change material layer pattern has formula,
C_{A}M_{B}[Ge_{X}Sb_{Y}Te_{(100-X-Y)}]_{(100-A-B)}
wherein C represents carbon, and M represents metal,
and wherein A, B, X and Y satisfy inequalities 0.2≦A≦25.0, 0.0≦B≦10.0, 0.1≦X≦30.0, and 0.1≦Y≦90.0.

26. The phase-change memory device of claim 22, wherein the lower electrode comprises a metal nitride, and wherein the phase-change memory device further comprises a second transition metal layer pattern between the lower electrode and the phase-change material layer pattern.

27. The phase-change memory device of claim 22, wherein the switching element comprises a diode on the substrate, and the lower electrode is electrically connected to the diode.

28. The phase-change memory device of claim 22, wherein the switching element comprises a transistor having a gate structure and an impurity region, the gate structure being on the substrate, and the impurity region being at an upper portion of the substrate adjacent to the gate structure,
and wherein the lower electrode is electrically connected to the impurity region.

29. A method of manufacturing a phase-change memory device, comprising:
forming a switching element on a substrate;
forming a lower electrode electrically connected to the switching element;
forming a phase-change material layer pattern on the lower electrode, the phase-change material layer pattern including GST and carbon;
forming a first transition metal layer pattern on the phase-change material layer pattern; and
forming an upper electrode on the first transition metal layer pattern.

30. The method of claim 29, wherein the first transition metal layer pattern is formed using at least one selected from the group consisting of titanium (Ti), vanadium (V), chromium (Cr), manganese (Mn), iron (Fe), cobalt (Co), nickel (Ni), zirconium (Zr), niobium (Nb), molybdenum (Mo), ruthenium (Ru), rhodium (Rh), palladium (Pd), hafnium (Hf), tantalum (Ta), tungsten (W), rhenium (Re), osmium (Os), iridium (Ir), and platinum (Pt).

31. The method of claim 29, wherein the upper electrode is formed using a metal nitride.

32. The method of claim 29, wherein the phase-change material layer pattern has formula,
C_{A}M_{B}[Ge_{X}Sb_{Y}Te_{(100-X-Y)}]_{(100-A-B)}
wherein C represents carbon, and M represents metal,
and wherein A, B, X and Y satisfy inequalities 0.2≦A≦25.0, 0.0≦B≦10.0, 0.1≦X≦30.0, and 0.1≦Y≦90.0.

33. The method of claim 29, wherein the lower electrode is formed using a metal nitride, and wherein the method further comprises forming a second transition metal layer pattern between the lower electrode and the phase-change material layer pattern.

34. The method of claim 29, wherein forming the switching element comprises forming a diode on the substrate, and the lower electrode is formed to be electrically connected to the diode.

35. The method of claim 29, wherein forming the switching element comprises:
forming a gate structure on the substrate; and
forming an impurity region at an upper portion of the substrate adjacent to the gate structure,
and wherein the lower electrode is formed to be electrically connected to the impurity region.
